(19) United States
(12) Patent Application Publication
(10) Pub. No.: US 2026/0170196 A1
(43) Pub. Date: Jun. 18, 2026

(54) PROJECTING IMPACT OF DESIGN CHANGE OF SYSTEM ON SYSTEM POWER-NOISE PROFILE

(71) Applicant: International Business Machines Corporation, Armonk, NY (US)

(72) Inventors: Thomas Strach, Wildberg (DE); Michael Romain, Long Island City, NY (US); Manuel Stumpf, Assamstadt (DE)

(21) Appl. No.: 18/981,267

(22) Filed: Dec. 13, 2024

(51) Int. Cl. G06F 30/20

(52) U.S. Cl. CPC G06F 30/20

(57) ABSTRACT

A computer-implemented method, system, and computer program product for projecting a design change impact on a power-noise profile. A workload is applied to a first system. A modeled system impedance profile of the first system is derived. Furthermore, a processor current profile of the workload for the first system is derived. A design change to the first system to create a second system is assumed. The modeled system impedance profile and the processor current profile for the second system are then scaled, where the scaling is made based on the design change. The scaled processor current profile is then convolved with the scaled modeled system impedance profile to generate a power-noise profile of the second system. The design change is implemented on the first system when the power-noise profile is within an acceptable range.

### TECHNICAL FIELD

The present disclosure relates generally to power-noise profiles.

### BACKGROUND

A power-noise simulation is a computer simulation that models and analyzes unwanted electrical noise fluctuations present on a power supply line within a circuit. Performing a power-noise simulation allows engineers to understand how these noise levels might affect the performance and stability of connected components, particularly in high-speed electronic systems where even small voltage fluctuations can be detrimental. A power-noise profile is the resulting data set from the power-noise simulation.

### SUMMARY

In one embodiment of the present disclosure, a computer-implemented method for projecting a design change impact on a power-noise profile comprises applying a workload to a first system. The method further comprises deriving a modeled system impedance profile of the first system. The method additionally comprises deriving a processor current profile of the workload for the first system. Furthermore, the method comprises assuming a design change to the first system to create a second system. Additionally, the method comprises scaling the modeled system impedance profile and the processor current profile for the second system, wherein the scaling is made based on the design change. In addition, the method comprises convolving the scaled processor current profile with the scaled modeled system impedance profile to generate a power-noise profile of the second system. The method further comprises implementing the design change to the first system when the power-noise profile is within an acceptable range.

Other forms of the embodiment of the computer-implemented method described above are in a system and in a computer program product.

The foregoing has outlined rather generally the features and technical advantages of one or more embodiments of the present disclosure in order that the detailed description of the present disclosure that follows may be better understood. Additional features and advantages of the present disclosure will be described hereinafter which may form the subject of the claims of the present disclosure.

### BRIEF DESCRIPTION OF THE DRAWINGS

A better understanding of the present disclosure can be obtained when the following detailed description is considered in conjunction with the following drawings, in which:

FIG. 1 illustrates an embodiment of the present disclosure of a communication system for practicing the principles of the present disclosure;

FIG. 2 is a diagram of the software components of the power-noise evaluator used for projecting the impact of a design change, such as a design change of a first system that is reflected on a second system, on the power-noise profile of the second system for a workload in accordance with an embodiment of the present disclosure;

FIG. 3 illustrates deconvolving the impedance profile with a given workload's voltage trace to generate a corresponding current trace in accordance with an embodiment of the present disclosure;

FIG. 4 illustrates the outputted unsmoothed generated current trace and the corresponding smoothed current trace in accordance with an embodiment of the present disclosure;

FIG. 5 illustrates the non-scaled output and the scaled output for a trivial workload in accordance with an embodiment of the present disclosure;

FIG. 6 illustrates the non-scaled output and the scaled output for a non-trivial workload in accordance with an embodiment of the present disclosure;

FIG. 7 illustrates an embodiment of the present disclosure of the hardware configuration of the computing device and the power-noise evaluator which is representative of a hardware environment for practicing the present disclosure;

FIG. 8 is a flowchart of a method for projecting the impact of a design change on the power-noise profile of the second system for a workload in accordance with an embodiment of the present disclosure; and

FIG. 9 is a flowchart of a method for deriving a processor current profile of the workload for the first system in accordance with an embodiment of the present disclosure.

### DETAILED DESCRIPTION

As stated above, a power-noise simulation is a computer simulation that models and analyzes unwanted electrical noise fluctuations present on a power supply line within a circuit. Performing a power-noise simulation allows engineers to understand how these noise levels might affect the performance and stability of connected components, particularly in high-speed electronic systems where even small voltage fluctuations can be detrimental. A power-noise profile is the resulting data set from the power-noise simulation.

The purpose of a power-noise simulation is to identify potential issues related to power supply noise, such as voltage drops, spikes, or ripple, which can disrupt signal integrity and cause malfunctions in sensitive circuits.

The simulation may include models of power supply components, such as capacitors, inductors, and voltage regulators, as well as the circuit's power distribution network, to accurately represent how noise propagates through the system. Furthermore, simulations can analyze various aspects of power noise, including its frequency spectrum, amplitude, and the impact on critical signal timings (jitter).

By running simulations with different design parameters, engineers can identify areas for improvement to mitigate power noise, such as adding decoupling capacitors or optimizing the power delivery network layout.

Power-noise simulations are typically performed on high-speed digital circuits (where sensitive signals can be easily corrupted by power supply fluctuations), power electronics (where the switching noise generated by power converters and its impact on the system are analyzed), and embedded systems (where the reliable operation of critical components in constrained power environments is ensured).

Unfortunately, current power-noise simulation techniques are only capable of projecting the impact of limited design changes (e.g., capacitance change) of a system (e.g., computing system, processor, etc.) on the system power-noise profile observed on a limited class of workloads (e.g., dl/dt step function, which corresponds to the derivative of a step function with respect to time “t”). A “power-noise profile” refers to a representation, such as a graphical representation, of the noise level (in terms of power) across different frequencies within a power supply or circuit thereby showing how much electrical noise is present at various frequencies. While such existing approaches provide some insight into the power-noise impact of a system design change (e.g., capacitance change), such approaches lack accuracy and flexibility.

The embodiments of the present disclosure provide a means for accurately and flexibly projecting the impact of a design change of a system (e.g., computing system, processor, etc.) on the system power-noise profile for a broader class of workloads, including non-trivial workloads (significant and complex set of tasks or operations that cannot be easily completed, requiring substantial effort and consideration, unlike a “trivial workload” which includes simple and straightforward tasks). A workload, as used herein, refers to the set of tasks or operations to be completed by the system. In one embodiment, a modeled system impedance profile of a first system (e.g., computing system, processor) is derived. A modeled system impedance profile, as used herein, refers to a representation, including a graphical representation, of how the impedance of a system changes across a range of frequencies. In one embodiment, the modeled system impedance profile is calculated using a mathematical model that simulates the system's electrical behavior, such as showing how much resistance the system presents to current flow at different frequencies. In one embodiment, a processor current profile of the workload for the first system is derived. A processor current profile of the workload, as used herein, refers to the specific set of performance settings currently applied to a processor and optimized to handle the demands of the current workload running on the system. That is, the processor current profile of the workload defines how the processor is dynamically adjusting its speed, power consumption, and other parameters to best suit the ongoing tasks. The modeled system impedance profile and the processor current profile are scaled to reflect a design change (e.g. design technology changes, such the place, connection, type and physical properties involving the physical components, and design power/current changes, such as voltage, current, impedance, noise of voltage, and noise of current involving the physical components) in a second system (e.g., computing system, processor). Reflect, as used herein, refers to the design changes between the first and second systems that are exhibited on the second system. Scaling, as used herein, refers to adjusting the simulated electrical characteristics of a system (e.g., impedance profile, processor current profile) to match the behavior of a new, modified system design thereby replicating the impact of the design change in the simulation environment. The scaled processor current profile is convolved with the scaled modeled system impedance profile to generate a power-noise profile of the second system. Convolution, as used herein, refers to a mathematical operation performed on two functions that produces a third function. In the context of convolving the scaled processor current profile with the scaled modeled system impedance profile to generate a power-noise profile of the second system, convolution involves calculating how the current fluctuations interact with the system impedance to produce voltage drops and resulting power noise at different points in time. In one embodiment, convolution is performed by multiplying each point of the current profile with the corresponding point of the impedance profile after shifting one relative to the other and summing up the results across all time points. In this manner, the impact of a design change of a system (e.g., computing system, processor, etc.) can be accurately and flexibly projected on the system power-noise profile for a broader class of workloads, including non-trivial workloads. A further description of these and other features will be provided below.

In some embodiments of the present disclosure, the present disclosure comprises a computer-implemented method, system, and computer program product for projecting a design change impact on a power-noise profile. In one embodiment of the present disclosure, a workload is applied to a first system. A modeled system impedance profile of the first system may then be derived. A modeled system impedance profile, as used herein, refers to a representation, including a graphical representation, of how the impedance of a system changes across a range of frequencies. In one embodiment, the modeled system impedance profile is calculated using a mathematical model that simulates the system's electrical behavior, such as showing how much resistance the system presents to current flow at different frequencies. Furthermore, a processor current profile of the workload for the first system is derived. A processor current profile for the workload, as used herein, refers to the specific set of performance settings currently applied to a processor and optimized to handle the demands of the current workload running on the system. That is, the processor current profile of the workload defines how the processor is dynamically adjusting its speed, power consumption, and other parameters to best suit the ongoing tasks. A design change to the first system to create a second system is assumed. The modeled system impedance profile and the processor current profile for the second system are then scaled, where the scaling is made based on the design change. Scaling, as used herein, refers to adjusting the simulated electrical characteristics of a system (e.g., impedance profile, processor current profile) to match the behavior of a new, modified system design thereby replicating the impact of the design change in the simulation environment. The scaled processor current profile is convolved with the scaled modeled system impedance profile to generate a power-noise profile of the second system. Convolution, as used herein, refers to a mathematical operation performed on two functions that produces a third function. In the context of convolving the scaled processor current profile with the scaled modeled system impedance profile to generate a power-noise profile of the second system, convolution involves calculating how the current fluctuations interact with the system impedance to produce voltage drops and resulting power noise at different points in time. The design change is implemented on the first system when the power-noise profile is within an acceptable range. In this manner, the impact of a design change of a system (e.g., computing system, processor, etc.) can be accurately and flexibly projected on the system power-noise profile for a broader class of workloads, including non-trivial workloads.

In the following description, numerous specific details are set forth to provide a thorough understanding of the present disclosure. However, it will be apparent to those skilled in the art that the present disclosure may be practiced without such specific details. In other instances, well-known circuits have been shown in block diagram form in order not to obscure the present disclosure in unnecessary detail. For the most part, details considering timing considerations and the like have been omitted inasmuch as such details are not necessary to obtain a complete understanding of the present disclosure and are within the skills of persons of ordinary skill in the relevant art.

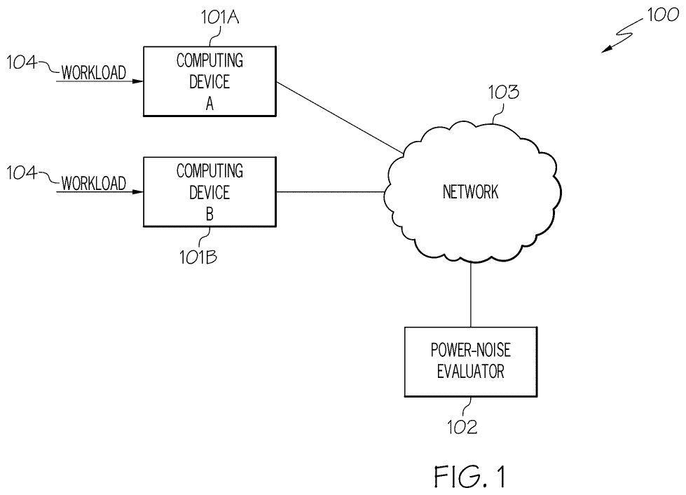

Referring now to the Figures in detail, FIG. 1 illustrates an embodiment of the present disclosure of a communication system 100 for practicing the principles of the present disclosure. Communication system 100 includes computing devices 101A-101B (identified as “Computing Device A,” and “Computing Device B,” respectively, in FIG. 1) connected to a power-noise evaluator 102 via a network 103. Computing devices 101A-101B may collectively or individually be referred to as computing devices 101 or computing device 101, respectively.

Computing device 101 may be any type of computing device (e.g., portable computing unit, Personal Digital Assistant (PDA), laptop computer, mobile device, tablet personal computer, smartphone, mobile phone, navigation device, gaming unit, desktop computer system, workstation, Internet appliance and the like) configured with the capability of connecting to network 103 and consequently communicating with other computing devices 101 and power-noise evaluator 102. It is noted that both computing device 101 and the user of computing device 101 may be identified with element number 101.

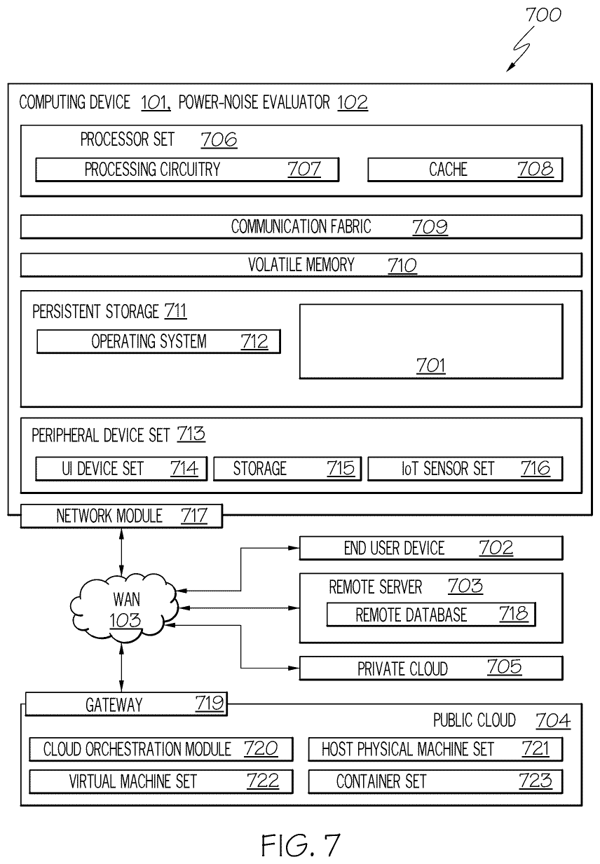

While FIG. 1 illustrates two computing devices 101, it is noted that system 100 may include any number of computing devices 101. In one embodiment, computing device 101 implements a distributed symmetric multiprocessing (SMP) system. A description of the hardware configuration of computing device 101 is provided further below in connection with FIG. 7.

Each computing device 101 may be configured to receive a workload 104 to be processed. A workload, as used herein, refers to the set of tasks or operations to be completed by the system, such as computing system 101 or the processor of computing system 101. Such a workload may include non-trivial workloads. A non-trivial workload, as used herein, refers to a significant and complex set of tasks or operations that cannot be easily completed, requiring substantial effort and consideration, unlike a “trivial workload” which includes simple and straightforward tasks.

In one embodiment, power-noise evaluator 102 is configured to project the impact of a design change, such as a design change of a first system (e.g., computing system 101A) that is reflected on a second system (e.g., computing system 101B), on the power-noise-profile for the second system for a workload, such as workload 104. A design change of a system, as used herein, refers to modifying the physical layout, power and/or current of the physical components (e.g., processor) within a system, which modifies the amount of electrical noise generated while it operates thereby modifying the power-noise profile of the system. The power-noise profile, as used herein, refers to a representation, such as a graphical representation, of the noise level (in terms of power) across different frequencies within a power supply or circuit thereby showing how much electrical noise is present at various frequencies. The projection of the impact of a design change, such as a design change of a first system that is reflected on a second system, on the power-noise-profile for the second system for a workload, as used herein, refers to estimating how a proposed modification to the design of a system will affect the level of power consumption and noise generated considering the demands placed on the system by its workload.

In one embodiment, such a design change of a first system (e.g., computing system 101A) may be reflected in the design of a second system (e.g., computing system 101B). That is, such a design change may correspond to the difference in design between the first and second systems.

In one embodiment, such a design change may correspond to a design technology change and/or a design power or current change. A design technology change, as used herein, refers to a change in the physical layout (e.g., place, connection) of the physical components or the characteristics and properties (e.g., type, physical properties) of the physical components. A design power or current change, as used herein, refers to the change in the power or current (e.g., voltage, current, impedance, noise of voltage, noise of current, etc.) of the physical components.

A further discussion regarding power-noise evaluator 102 projecting the impact of a design change, such as a design change of a first system (e.g., computing system 101A) that is reflected on a second system (e.g., computing system 101B), on the power-noise-profile for the second system for a workload, such as workload 104, is provided further below.

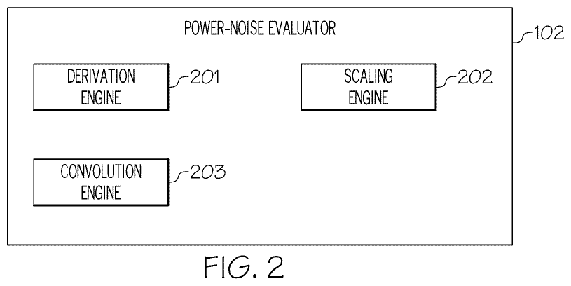

Furthermore, a description of the software components of power-noise evaluator 102 is provided below in connection with FIG. 2 and a description of the hardware configuration of power-noise evaluator 102 is provided further below in connection with FIG. 7.

System 100 is not to be limited in scope to any one particular network architecture. System 100 may include any number of computing devices 101, power-noise evaluators 102, networks 103, and workloads 104.

Referring now to FIG. 2, FIG. 2 is a diagram of the software components of power-noise evaluator 102 used for projecting the impact of a design change, such as a design change of a first system (e.g., computing system 101A) that is reflected on a second system (e.g., computing system 101B), on the power-noise-profile for the second system for a workload, such as a non-trivial workload, in accordance with an embodiment of the present disclosure.

As shown in FIG. 2, in conjunction with FIG. 1, power-noise evaluator 102 includes derivation engine 201 configured to derive a modeled system impedance profile of a first system (e.g., computing device 101A, processor of computing device 101A).

A modeled system impedance profile, as used herein, refers to a representation, including a graphical representation, of how the impedance of a system changes across a range of frequencies. In one embodiment, the modeled system impedance profile is calculated using a mathematical model that simulates the system's electrical behavior, such as showing how much resistance the system presents to current flow at different frequencies.

In one embodiment, derivation engine 201 derives a modeled system impedance profile of a first system (e.g., computing device 101A, processor of computing device 101A) by leveraging empirical feedback. Leveraging empirical feedback, as used herein, refers to using real-world data (empirical feedback) to refine and adjust a mathematical model of the system's impedance characteristics thereby creating a more accurate representation of how the system behaves in practice.

In one embodiment, derivation engine 201 builds a theoretical model of the system's impedance based on its components and design parameters. In one embodiment, derivation engine 201 builds such a model by analyzing the individual components within the system, such as the resistors (R), capacitors (C), and inductors (L). Such components may then be combined according to the circuit topology using the rules of series and parallel combinations taking into account the frequency dependence of reactive components (e.g., capacitors, inductors) to calculate the complex impedance at different frequencies. In one embodiment, derivation engine 201 utilizes various software tools for building such a model, which may include, but are not limited to, Altium Designer®, Cadence® PSpice®, Ansys® Q3D Extractor®, etc.

In one embodiment, derivation engine 201 gathers empirical data from real-world experiments or system operations, capturing how the system responds to different inputs (e.g., voltage, current) under various conditions. For example, derivation engine 201 applies controlled input signals to the system while simultaneously measuring the corresponding output signals, where such input signals and conditions (e.g., temperature, frequency, load) are varied in order to observe the system's behavior across different scenarios. In one embodiment, derivation engine 201 utilizes various software tools for empirical data collection as discussed above, which may include, but are not limited to, LabVIEW®, DewesoftX, Matlab®, etc.

In one embodiment, derivation engine 201 analyzes the captured data to identify discrepancies between the initial model and the actual system behavior. This information is then used to adjust the parameters within the model to better match the observed empirical data. In one embodiment, derivation engine 201 utilizes various software tools for data analysis and parameter tuning as discussed above, which may include, but are not limited to, Matchlt, SAS®, Matlab®, etc.

In one embodiment, derivation engine 201 derives a processor current profile of the workload (e.g., workload 104) for the first system (e.g., computing device 101A, processor of computing device 101A). A processor current profile of the workload, as used herein, refers to the specific set of performance settings currently applied to a processor and optimized to handle the demands of the current workload running on the system. That is, the processor current profile of the workload defines how the processor is dynamically adjusting its speed, power consumption, and other parameters to best suit the ongoing tasks.

In one embodiment, derivation engine 201 derives such a processor current profile of the workload for the first system by determining the modeled system impedance profile of the first system and an associated response function.

As discussed above, derivation engine 201 is configured to derive the modeled system impedance profile of the first system. The associated response function is determined by derivation engine 201 by calculating the inverse of the impedance function (admittance function) across the frequency range of interest. That is, the associated response function is determined by derivation engine 201 by treating the impedance as a transfer function where the input is current and the output is voltage thereby providing the system's response to a given current input at different frequencies.

In one embodiment, derivation engine 201 expresses the impedance as a function of frequency, where the modeled system impedance is represented as a complex function of frequency (Z(ω) where ω is the angular frequency). The admittance (Y(ω)) is the reciprocal of impedance, calculated as Y(ω)=1/Z(ω). In one embodiment, such a calculated admittance is a complex function representing the system's ability to conduct current at different frequencies. As a response, the admittance function describes how the system responds to a current input at various frequencies, with the magnitude representing the current flow and the phase angle indicating the timing relationship between the current and the voltage.

In one embodiment, derivation engine 201 utilizes various software tools for determining the modeled system impedance profile of the first system and an associated response function as discussed above, which may include, but are not limited to, Zview®, Zplot, EasyEIS, Matlab®, etc.

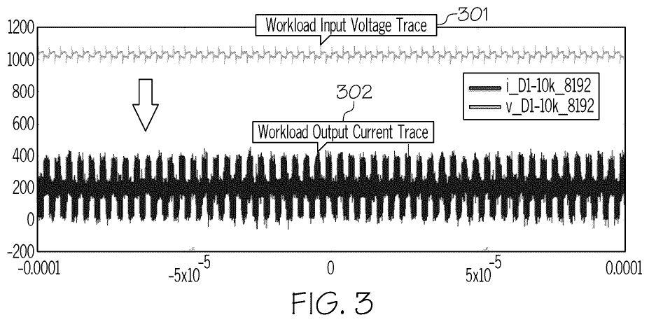

Furthermore, in connection with deriving a processor current profile of the workload for the first system, derivation engine 201 deconvolves the modeled system impedance profile of the first system with a voltage trace of the workload to generate a corresponding current trace as illustrated in FIG. 3.

In one embodiment, derivation engine 201 deconvolves the modeled system impedance profile of the first system with a voltage trace of the workload to generate a corresponding current trace by performing a mathematical operation that divides the voltage trace by the system impedance at each point in time thereby applying the fundamental electrical relationship: current=voltage/impedance.

In one embodiment, derivation engine 201 deconvolves the modeled system impedance profile of the first system with a voltage trace of the workload to generate a corresponding current trace by loading both the modeled system impedance profile, such as a function of frequency or time, and the voltage trace into an analysis software (e.g., Matlab®, LTspice®). In one embodiment, derivation engine 201 ensures the time scales of both the impedance and voltage data are properly aligned to correspond to the same time points. In one embodiment, if the impedance data is in the frequency domain, derivation engine 201 performs a Fast Fourier Transform (FFT) to convert the impedance data to the time domain prior to deconvolution. In one embodiment, derivation engine 201 then performs the deconvolution calculation, looping through each time point in the data set. At each time point, the corresponding impedance value is retrieved from the system impedance profile. The voltage value is then divided at that time point by the impedance value to calculate the current value. The resulting data set corresponds to the current trace corresponding to the applied voltage and system impedance as shown in FIG. 3.

Referring to FIG. 3, FIG. 3 illustrates deconvolving the impedance profile with a given workload's voltage trace to generate a corresponding current trace in accordance with an embodiment of the present disclosure.

As shown in FIG. 3, using the workload's voltage trace 301, a corresponding current trace 302 is generated by performing the operations discussed above.

In one embodiment, derivation engine 201 utilizes various software tools for deconvolving the modeled system impedance profile of the first system with a voltage trace of the workload to generate a corresponding current trace using the operations discussed above, which may include, but are not limited to, Zview®, Zplot, Cadence® Virtuoso, etc.

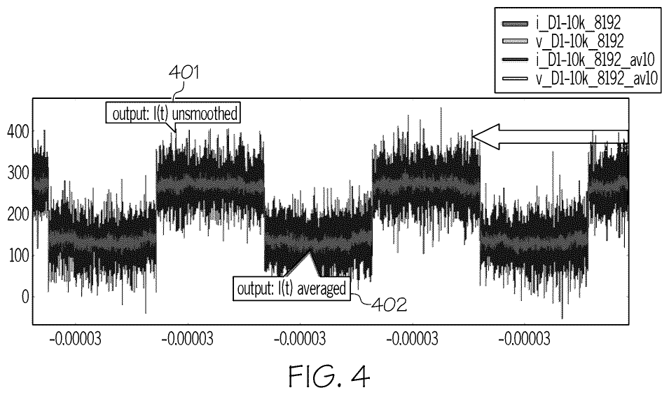

Furthermore, in one embodiment, derivation engine 201 may optionally average the generated current trace across multiple repetition cycles to smooth out any short-term fluctuations thereby providing a more stable, representative “mean” value of the current trace as shown in FIG. 4.

FIG. 4 illustrates the outputted unsmoothed generated current trace and the corresponding smoothed current trace in accordance with an embodiment of the present disclosure.

As shown in FIG. 4, the outputted unsmoothed generated current trace 401 (I (t) unsmoothed, representing the unsmoothed current at a specific time) is averaged across multiple repetition cycles to smooth out any short-term fluctuations thereby providing a more stable, representative “mean” value of the current trace (i.e., the smoothed current trace 402) (I (t) averaged, representing the averaged current at a specific time).

Returning to FIG. 2, in one embodiment, derivation engine 201 simulates the electrical characteristics (e.g., capacitances, current values) of the system impedance profile and the processor current profile.

In one embodiment, derivation engine 201 utilizes various software tools for performing such a simulation, including, but not limited to, Ansys® HFSS, Ansys® Maxwell, Matlab®, Siemens® PSS, etc.

Furthermore, in one embodiment, a design change (discussed further below) to the first system to create a second system (e.g., computing device 101B, processor of computing device 101B) is assumed.

Power-noise evaluator 102 further includes scaling engine 202 configured to scale the modeled system impedance profile and the processor current profile for the second system (e.g., computing device 101B, processor of computing device 101B), where the scaling is made based on the design change. Scaling, as used herein, refers to adjusting the simulated electrical characteristics of a system (e.g., impedance profile, processor current profile) to match the behavior of a new, modified system design thereby replicating the impact of the design change in the simulation environment.

A design change of a system, as used herein, refers to modifying the physical layout, power and/or current of the physical components (e.g., processor) within a system, which modifies the amount of electrical noise generated while it operates thereby modifying the power-noise profile of the system. The power-noise profile, as used herein, refers to a representation, such as a graphical representation, of the noise level (in terms of power) across different frequencies within a power supply or circuit thereby showing how much electrical noise is present at various frequencies.

In one embodiment, such a design change of a first system (e.g., computing system 101A) may be reflected in the design of a second system (e.g., computing system 101B). Reflect, as used herein, refers to the design changes between the first and second systems that are exhibited on the second system. That is, such a design change may correspond to the difference in design between the first and second systems.

In one embodiment, such a design change may correspond to a design technology change and/or a design power or current change. A design technology change, as used herein, refers to a change in the physical layout (e.g., place, connection) of the physical components or the characteristics and properties (e.g., type, physical properties) of the physical components of the second system. A design power or current change, as used herein, refers to the change in the power or current (e.g., voltage, current, impedance, noise of voltage, noise of current, etc.) of the physical components of the second system.

In one embodiment, scaling engine 202 scales the modeled system impedance profile and the processor current profile to reflect a design change in a second system (e.g., computing device 101B, processor of computing device 101B) by scaling the capacitances in the modeled impedance profile to reflect a design technology change in the second system.

In one embodiment, scaling engine 202 scales the capacitances in the modeled impedance profile to reflect a design technology change in the second system by calculating new capacitance values based on the altered physical layout and/or characteristics and/or properties of the physical components in the second system. For example, such new capacitance values may be computed using the capacitance formula (C=εA/d, where ε is the dielectric constant, A is the surface area of the conductor plates in the capacitor, and d is the distance between the conductor plates) and adjusting the corresponding capacitance values in the impedance profile. In one embodiment, such scaling factors are derived from the changes in the dielectric constant or conductor geometry.

Scaling engine 202 utilizes various software tools for scaling the capacitances in the modeled impedance profile to reflect a design technology change in the second system, which may include, but are not limited to, Altium Designer®, Cadence® Allegro, Mentor Graphics® HyperLynx, etc.

Furthermore, in one embodiment, scaling engine 202 scales the modeled system impedance profile and the processor current profile to reflect a design change in a second system (e.g., computing device 101B, processor of computing device 101B) by scaling the processor current profile to reflect a design power or current change in the second system.

In one embodiment, scaling engine 202 scales the processor current profile to reflect a design power or current change in the second system by adjusting the current values proportionally based on the power/current ratio difference between the first and second systems. In one embodiment, such an adjustment is achieved by multiplying the current values of the processor current profile by a scaling factor derived from the power/current change ratio.

Scaling engine 202 utilizes various software tools for scaling the processor current profile to reflect a design power or current change in the second system, which may include, but are not limited to, turbostat, LTpowerPlanner®, etc.

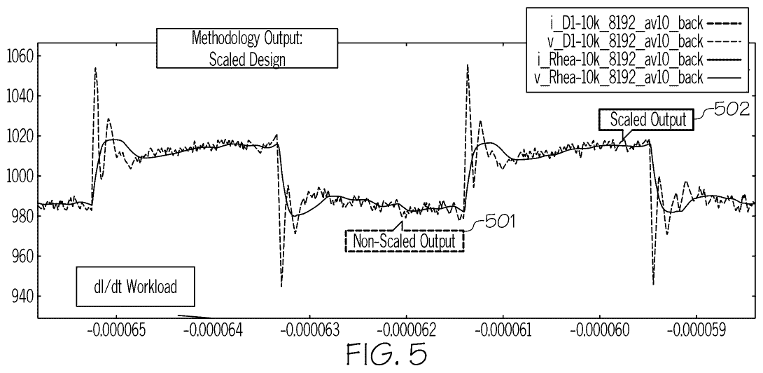

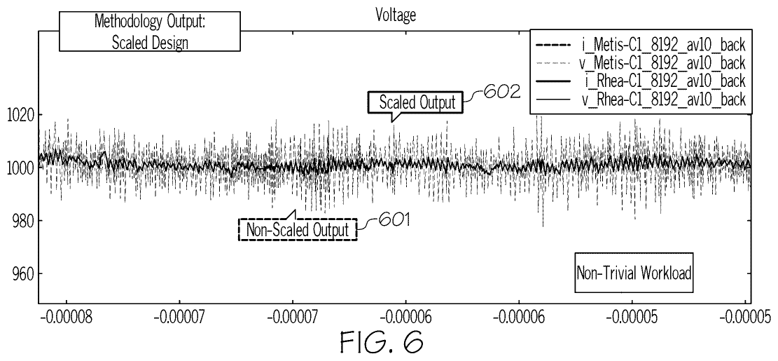

An illustration of scaling the modeled system impedance profile and processor current profile to reflect a design change in the second system is provided in FIGS. 5 and 6.

FIG. 5 illustrates the non-scaled output 501 and the scaled output 502 for a trivial workload (e.g., dl/dt workload) in accordance with an embodiment of the present disclosure.

FIG. 6 illustrates the non-scaled output 601 and the scaled output 602 for a non-trivial workload in accordance with an embodiment of the present disclosure. As discussed above, a non-trivial workload, as used herein, refers to a significant and complex set of tasks or operations that cannot be easily completed, requiring substantial effort and consideration, unlike a “trivial workload” which includes simple and straightforward tasks.

Returning to FIG. 2, power-noise evaluator 102 additionally includes convolution engine 203 configured to convolve the scaled processor current profile with the scaled modeled system impedance profile to generate a power-noise profile of the second system (e.g., computing device 101B, processor of computing device 101B). Convolution, as used herein, refers to a mathematical operation performed on two functions that produces a third function.

In the context of convolving the scaled processor current profile with the scaled modeled system impedance profile to generate a power-noise profile of the second system, convolution involves calculating how the current fluctuations interact with the system impedance to produce voltage drops and resulting power noise at different points in time. In one embodiment, convolution engine 203 performs convolution by multiplying each point of the current profile with the corresponding point of the impedance profile after shifting one relative to the other and summing up the results across all time points.

In one embodiment, convolution engine 203 performs such a convolution by multiplying the two profiles in the frequency domain after scaling them appropriately to account for the system changes between the first and second systems. In one embodiment, the scaled processor current profile and the scaled modeled system impedance profile are converted to the frequency domain, such as via the Fast Fourier Transform (FFT) algorithm. The frequency domain representations of the scaled processor current profile and the scaled modeled system impedance profile are multiplied element-wise. Such a multiplication performs the convolution operation in the time domain. Convolution engine 203 then performs an inverse FFT on such a product to obtain the power-noise profile in the time domain, which represents the impact on the power-noise profile due to the design change for non-trivial workloads.

In one embodiment, throttling logic may be incorporated into the simulation discussed herein to represent a design methodology change. Throttling logic, as used herein, refers to a set of rules that intentionally limits the rate at which something happens, such as restricting the number of tasks or operations in a workload to be handled per unit of time.

In one embodiment, the design change is implemented on the first system when the power-noise profile is within an acceptable range, which may be user-designated.

In this manner, the impact of a design change of a system (e.g., computing system, processor, etc.) can be accurately and flexibly projected on the system power-noise profile for a broader class of workloads, including non-trivial workloads.

A further description of these and other features is provided below in connection with the discussion of the method for projecting the impact of a design change, such as a design change of a first system (e.g., computing system 101A) that is reflected on a second system (e.g., computing system 101B), on the power-noise-profile for the second system for a workload.

Prior to the discussion of the method for projecting the impact of a design change, such as a design change of a first system (e.g., computing system 101A) that is reflected on a second system (e.g., computing system 101B), on the power-noise-profile for the second system for a workload, a description of the hardware configuration of computing device 101 (FIG. 1) and power-noise evaluator 102 (FIG. 1) is provided below in connection with FIG. 7.

Referring now to FIG. 7, in conjunction with FIG. 1, FIG. 7 illustrates an embodiment of the present disclosure of the hardware configuration of computing device 101 and power-noise evaluator 102 which is representative of a hardware environment for practicing the present disclosure.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 700 contains an example of an environment for the execution of at least some of the computer code which is stored in block 701 involved in performing the disclosed methods for power-noise evaluator 102, such as projecting the impact of a design change, such as a design change of a first system (e.g., computing system 101A) that is reflected on a second system (e.g., computing system 101B), on the power-noise-profile for the second system for a workload. In addition to block 701, computing environment 700 includes, for example, computing device 101/power-noise evaluator 102, network 103, such as a wide area network (WAN), end user device (EUD) 702, remote server 703, public cloud 704, and private cloud 705. In this embodiment, computing device 101/power-noise evaluator 102 includes processor set 706 (including processing circuitry 707 and cache 708), communication fabric 709, volatile memory 710, persistent storage 711 (including operating system 712 and block 701, as identified above), peripheral device set 713 (including user interface (UI) device set 714, storage 715, and Internet of Things (IoT) sensor set 716), and network module 717. Remote server 703 includes remote database 718. Public cloud 704 includes gateway 719, cloud orchestration module 720, host physical machine set 721, virtual machine set 722, and container set 723.

Computing device 101/power-noise evaluator 102 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 718. As is well understood in the art of computer technology, and depending upon the technology, performance of a computer-implemented method may be distributed among multiple computers and/or between multiple locations. On the other hand, in this presentation of computing environment 700, detailed discussion is focused on a single computer, specifically computing device 101/power-noise evaluator 102, to keep the presentation as simple as possible. Computing device 101/power-noise evaluator 102 may be located in a cloud, even though it is not shown in a cloud in FIG. 7. On the other hand, computing device 101/power-noise evaluator 102 is not required to be in a cloud except to any extent as may be affirmatively indicated.

Processor set 706 includes one, or more, computer processors of any type now known or to be developed in the future. Processing circuitry 707 may be distributed over multiple packages, for example, multiple, coordinated integrated circuit chips. Processing circuitry 707 may implement multiple processor threads and/or multiple processor cores. Cache 708 is memory that is located in the processor chip package(s) and is typically used for data or code that should be available for rapid access by the threads or cores running on processor set 706. Cache memories are typically organized into multiple levels depending upon relative proximity to the processing circuitry. Alternatively, some, or all, of the cache for the processor set may be located “off chip.” In some computing environments, processor set 706 may be designed for working with qubits and performing quantum computing.

Computer readable program instructions are typically loaded onto computing device 101/power-noise evaluator 102 to cause a series of operational steps to be performed by processor set 706 of computing device 101/power-noise evaluator 102 and thereby effect a computer-implemented method, such that the instructions thus executed will instantiate the methods specified in flowcharts and/or narrative descriptions of computer-implemented methods included in this document (collectively referred to as “the disclosed methods”). These computer readable program instructions are stored in various types of computer readable storage media, such as cache 708 and the other storage media discussed below. The program instructions, and associated data, are accessed by processor set 706 to control and direct performance of the disclosed methods. In computing environment 700, at least some of the instructions for performing the disclosed methods may be stored in block 701 in persistent storage 711.

Communication fabric 709 is the signal conduction paths that allow the various components of computing device 101/power-noise evaluator 102 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 710 is any type of volatile memory now known or to be developed in the future. Examples include dynamic type random access memory (RAM) or static type RAM. Typically, the volatile memory is characterized by random access, but this is not required unless affirmatively indicated. In computing device 101/power-noise evaluator 102, the volatile memory 710 is located in a single package and is internal to computing device 101/power-noise evaluator 102, but, alternatively or additionally, the volatile memory may be distributed over multiple packages and/or located externally with respect to computing device 101/power-noise evaluator 102.

Persistent Storage 711 is any form of non-volatile storage for computers that is now known or to be developed in the future. The non-volatility of this storage means that the stored data is maintained regardless of whether power is being supplied to computing device 101/power-noise evaluator 102 and/or directly to persistent storage 711. Persistent storage 711 may be a read only memory (ROM), but typically at least a portion of the persistent storage allows writing of data, deletion of data and re-writing of data. Some familiar forms of persistent storage include magnetic disks and solid state storage devices. Operating system 712 may take several forms, such as various known proprietary operating systems or open source Portable Operating System Interface type operating systems that employ a kernel. The code included in block 701 typically includes at least some of the computer code involved in performing the disclosed methods.

Peripheral device set 713 includes the set of peripheral devices of computing device 101/power-noise evaluator 102. Data communication connections between the peripheral devices and the other components of computing device 101/power-noise evaluator 102 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 714 may include components such as a display screen, speaker, microphone, wearable devices (such as goggles and smart watches), keyboard, mouse, printer, touchpad, game controllers, and haptic devices. Storage 715 is external storage, such as an external hard drive, or insertable storage, such as an SD card. Storage 715 may be persistent and/or volatile. In some embodiments, storage 715 may take the form of a quantum computing storage device for storing data in the form of qubits. In embodiments where computing device 101/power-noise evaluator 102 is required to have a large amount of storage (for example, where computing device 101/power-noise evaluator 102 locally stores and manages a large database) then this storage may be provided by peripheral storage devices designed for storing very large amounts of data, such as a storage area network (SAN) that is shared by multiple, geographically distributed computers. IoT sensor set 716 is made up of sensors that can be used in Internet of Things applications. For example, one sensor may be a thermometer and another sensor may be a motion detector.

Network module 717 is the collection of computer software, hardware, and firmware that allows computing device 101/power-noise evaluator 102 to communicate with other computers through WAN 103. Network module 717 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 717 are performed on the same physical hardware device. In other embodiments (for example, embodiments that utilize software-defined networking (SDN)), the control functions and the forwarding functions of network module 717 are performed on physically separate devices, such that the control functions manage several different network hardware devices. Computer readable program instructions for performing the disclosed methods can typically be downloaded to computing device 101/power-noise evaluator 102 from an external computer or external storage device through a network adapter card or network interface included in network module 717.

WAN 103 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 702 is any computer system that is used and controlled by an end user (for example, a customer of an enterprise that operates computing device 101/power-noise evaluator 102), and may take any of the forms discussed above in connection with computing device 101/power-noise evaluator 102. EUD 702 typically receives helpful and useful data from the operations of computing device 101/power-noise evaluator 102. For example, in a hypothetical case where computing device 101/power-noise evaluator 102 is designed to provide a recommendation to an end user, this recommendation would typically be communicated from network module 717 of computing device 101/power-noise evaluator 102 through WAN 103 to EUD 702. In this way, EUD 702 can display, or otherwise present, the recommendation to an end user. In some embodiments, EUD 702 may be a client device, such as thin client, heavy client, mainframe computer, desktop computer and so on.

Remote server 703 is any computer system that serves at least some data and/or functionality to computing device 101/power-noise evaluator 102. Remote server 703 may be controlled and used by the same entity that operates computing device 101/power-noise evaluator 102. Remote server 703 represents the machine(s) that collect and store helpful and useful data for use by other computers, such as computing device 101/power-noise evaluator 102. For example, in a hypothetical case where computing device 101/power-noise evaluator 102 is designed and programmed to provide a recommendation based on historical data, then this historical data may be provided to computing device 101/power-noise evaluator 102 from remote database 718 of remote server 703.

Public cloud 704 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 704 is performed by the computer hardware and/or software of cloud orchestration module 720. The computing resources provided by public cloud 704 are typically implemented by virtual computing environments that run on various computers making up the computers of host physical machine set 721, which is the universe of physical computers in and/or available to public cloud 704. The virtual computing environments (VCEs) typically take the form of virtual machines from virtual machine set 722 and/or containers from container set 723. It is understood that these VCEs may be stored as images and may be transferred among and between the various physical machine hosts, either as images or after instantiation of the VCE. Cloud orchestration module 720 manages the transfer and storage of images, deploys new instantiations of VCEs and manages active instantiations of VCE deployments. Gateway 719 is the collection of computer software, hardware, and firmware that allows public cloud 704 to communicate through WAN 103.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 705 is similar to public cloud 704, except that the computing resources are only available for use by a single enterprise. While private cloud 705 is depicted as being in communication with WAN 103 in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 704 and private cloud 705 are both part of a larger hybrid cloud.

Block 701 of power-noise evaluator 102 further includes the software components discussed above in connection with FIGS. 2-6 to project the impact of a design change, such as a design change of a first system (e.g., computing system 101A) that is reflected on a second system (e.g., computing system 101B), on the power-noise-profile for the second system for a workload. In one embodiment, such components may be implemented in hardware. The functions discussed above performed by such components are not generic computer functions. As a result, power-noise evaluator 102 is a particular machine that is the result of implementing specific, non-generic computer functions.

In one embodiment, the functionality of such software components of power-noise evaluator 102, including the functionality for projecting the impact of a design change, such as a design change of a first system (e.g., computing system 101A) that is reflected on a second system (e.g., computing system 101B), on the power-noise-profile for the second system for a workload, may be embodied in an application specific integrated circuit.

As stated above, the purpose of a power-noise simulation is to identify potential issues related to power supply noise, such as voltage drops, spikes, or ripple, which can disrupt signal integrity and cause malfunctions in sensitive circuits. The simulation may include models of power supply components, such as capacitors, inductors, and voltage regulators, as well as the circuit's power distribution network, to accurately represent how noise propagates through the system. Furthermore, simulations can analyze various aspects of power noise, including its frequency spectrum, amplitude, and the impact on critical signal timings (jitter). By running simulations with different design parameters, engineers can identify areas for improvement to mitigate power noise, such as adding decoupling capacitors or optimizing the power delivery network layout. Power-noise simulations are typically performed on high-speed digital circuits (where sensitive signals can be easily corrupted by power supply fluctuations), power electronics (where the switching noise generated by power converters and its impact on the system are analyzed), and embedded systems (where the reliable operation of critical components in constrained power environments is ensured). Unfortunately, current power-noise simulation techniques are only capable of projecting the impact of limited design changes (e.g., capacitance change) of a system (e.g., computing system, processor, etc.) on the system power-noise profile observed on a limited class of workloads (e.g., dl/dt step function, which corresponds to the derivative of a step function with respect to time “t”). A “power-noise profile” refers to a representation, such as a graphical representation, of the noise level (in terms of power) across different frequencies within a power supply or circuit thereby showing how much electrical noise is present at various frequencies. While such existing approaches provide some insight into the power-noise impact of a system design change (e.g., capacitance change), such approaches lack accuracy and flexibility.

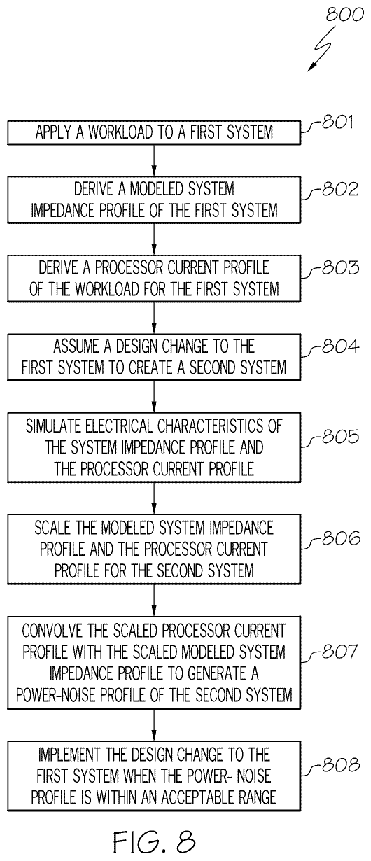

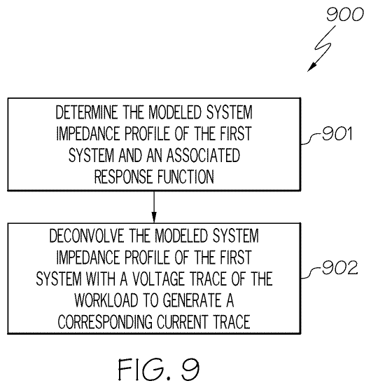

The embodiments of the present disclosure provide a means for accurately and flexibly projecting the impact of a design change of a system (e.g., computing system, processor, etc.) on the system power-noise profile for a broader class of workloads, including non-trivial workloads, as discussed below in connection with FIGS. 8-9. FIG. 8 is a flowchart of a method for projecting the impact of a design change, such as a design change of a first system (e.g., computing system 101A) that is reflected on a second system (e.g., computing system 101B), on the power-noise profile of the second system for a workload. FIG. 9 is a flowchart of a method for deriving a processor current profile of the workload for the first system.

As stated above, FIG. 8 is a flowchart of a method 800 for projecting the impact of a design change, such as a design change of a first system (e.g., computing system 101A) that is reflected on a second system (e.g., computing system 101B), on the power-noise profile of the second system for a workload in accordance with an embodiment of the present disclosure.

Referring to FIG. 8, in conjunction with FIGS. 1-7, in step 801, a workload, such as workload 104, is applied to a first system (e.g., computing device 101A, processor computing device 101A).

In step 802, derivation engine 201 of power-noise evaluator 102 derives a modeled system impedance profile of a first system (e.g., computing device 101A, processor of computing device 101A).

As stated above, a modeled system impedance profile, as used herein, refers to a representation, including a graphical representation, of how the impedance of a system changes across a range of frequencies. In one embodiment, the modeled system impedance profile is calculated using a mathematical model that simulates the system's electrical behavior, such as showing how much resistance the system presents to current flow at different frequencies.

In one embodiment, derivation engine 201 derives a modeled system impedance profile of a first system (e.g., computing device 101A, processor of computing device 101A) by leveraging empirical feedback. Leveraging empirical feedback, as used herein, refers to using real-world data (empirical feedback) to refine and adjust a mathematical model of the system's impedance characteristics thereby creating a more accurate representation of how the system behaves in practice.

In one embodiment, derivation engine 201 builds a theoretical model of the system's impedance based on its components and design parameters. In one embodiment, derivation engine 201 builds such a model by analyzing the individual components within the system, such as the resistors (R), capacitors (C), and inductors (L). Such components may then be combined according to the circuit topology using the rules of series and parallel combinations taking into account the frequency dependence of reactive components (e.g., capacitors, inductors) to calculate the complex impedance at different frequencies. In one embodiment, derivation engine 201 utilizes various software tools for building such a model, which may include, but are not limited to, Altium Designer®, Cadence® PSpice®, Ansys® Q3D Extractor®, etc.

In one embodiment, derivation engine 201 gathers empirical data from real-world experiments or system operations, capturing how the system responds to different inputs (e.g., voltage, current) under various conditions. For example, derivation engine 201 applies controlled input signals to the system while simultaneously measuring the corresponding output signals, where such input signals and conditions (e.g., temperature, frequency, load) are varied in order to observe the system's behavior across different scenarios. In one embodiment, derivation engine 201 utilizes various software tools for empirical data collection as discussed above, which may include, but are not limited to, LabVIEW®, DewesoftX, Matlab®, etc.

In one embodiment, derivation engine 201 analyzes the captured data to identify discrepancies between the initial model and the actual system behavior. This information is then used to adjust the parameters within the model to better match the observed empirical data. In one embodiment, derivation engine 201 utilizes various software tools for data analysis and parameter tuning as discussed above, which may include, but are not limited to, Matchlt, SAS®, Matlab®, etc.

In strep 803, derivation engine 201 of nose-profile evaluator 102 derives a processor current profile of the workload (e.g., workload 104) for the first system (e.g., computing device 101A, processor of computing device 101A).

As discussed above, a processor current profile of the workload, as used herein, refers to the specific set of performance settings currently applied to a processor and optimized to handle the demands of the current workload running on the system. That is, the processor current profile of the workload defines how the processor is dynamically adjusting its speed, power consumption, and other parameters to best suit the ongoing tasks.

A further discussion regarding derivation engine 201 deriving the processor current profile of the workload (e.g., workload 104) for the first system (e.g., computing device 101A, processor of computing device 101A) is provided below in connection with FIG. 9.

FIG. 9 is a flowchart of a method 900 for deriving a processor current profile of the workload for the first system in accordance with an embodiment of the present disclosure.

Referring to FIG. 9, in conjunction with FIGS. 1-8, in step 901, derivation engine 201 of power-noise evaluator 102 determines the modeled system impedance profile of the first system and an associated response function.

As discussed above, derivation engine 201 is configured to derive the modeled system impedance profile of the first system. The associated response function is determined by derivation engine 201 by calculating the inverse of the impedance function (admittance function) across the frequency range of interest. That is, the associated response function is determined by derivation engine 201 by treating the impedance as a transfer function where the input is current and the output is voltage thereby providing the system's response to a given current input at different frequencies.

In one embodiment, derivation engine 201 expresses the impedance as a function of frequency, where the modeled system impedance is represented as a complex function of frequency (Z(ω) where ω is the angular frequency). The admittance (Y(ω)) is the reciprocal of impedance, calculated as Y(ω)=1/Z(ω). In one embodiment, such a calculated admittance is a complex function representing the system's ability to conduct current at different frequencies. As a response, the admittance function describes how the system responds to a current input at various frequencies, with the magnitude representing the current flow and the phase angle indicating the timing relationship between the current and the voltage.

In one embodiment, derivation engine 201 utilizes various software tools for determining the modeled system impedance profile of the first system and an associated response function as discussed above, which may include, but are not limited to, Zview®, Zplot, EasyEIS, Matlab®, etc.

In step 902, derivation engine 201 of power-noise evaluator 102 deconvolves the modeled system impedance profile of the first system with a voltage trace of the workload to generate a corresponding current trace as illustrated in FIG. 3.

As stated above, in one embodiment, derivation engine 201 deconvolves the modeled system impedance profile of the first system with a voltage trace of the workload to generate a corresponding current trace by performing a mathematical operation that divides the voltage trace by the system impedance at each point in time thereby applying the fundamental electrical relationship: current=voltage/impedance.

In one embodiment, derivation engine 201 deconvolves the modeled system impedance profile of the first system with a voltage trace of the workload to generate a corresponding current trace by loading both the modeled system impedance profile, such as a function of frequency or time, and the voltage trace into an analysis software (e.g., Matlab®, LTspice®). In one embodiment, derivation engine 201 ensures the time scales of both the impedance and voltage data are properly aligned to correspond to the same time points. In one embodiment, if the impedance data is in the frequency domain, derivation engine 201 performs a Fast Fourier Transform (FFT) to convert the impedance data to the time domain prior to deconvolution. In one embodiment, derivation engine 201 then performs the deconvolution calculation, looping through each time point in the data set. At each time point, the corresponding impedance value is retrieved from the system impedance profile. The voltage value is then divided at that time point by the impedance value to calculate the current value. The resulting data set corresponds to the current trace corresponding to the applied voltage and system impedance as shown in FIG. 3.

As illustrated in FIG. 3, using the workload's voltage trace 301, a corresponding current trace 302 is generated by performing the operations discussed above.

In one embodiment, derivation engine 201 utilizes various software tools for deconvolving the modeled system impedance profile of the first system with a voltage trace of the workload to generate a corresponding current trace using the operations discussed above, which may include, but are not limited to, Zview®, Zplot, Cadence® Virtuoso, etc.

Furthermore, in one embodiment, derivation engine 201 may optionally average the generated current trace across multiple repetition cycles to smooth out any short-term fluctuations thereby providing a more stable, representative “mean” value of the current trace as shown in FIG. 4.

As illustrated in FIG. 4, the outputted unsmoothed generated current trace 401 (I (t) unsmoothed, representing the unsmoothed current at a specific time) is averaged across multiple repetition cycles to smooth out any short-term fluctuations thereby providing a more stable, representative “mean” value of the current trace (i.e., the smoothed current trace 402) (I (t) averaged, representing the averaged current at a specific time).

Returning to FIG. 8, in conjunction with FIGS. 1-7 and 9, in step 804, a design change to the first system (e.g., computing device 101A, processor of computing device 101A) to create a second system (e.g., computing device 101B, processor of computing device 101B) is assumed.

In step 805, derivation engine 201 simulates the electrical characteristics (e.g., capacitances, current values) of the system impedance profile and the processor current profile.

In one embodiment, derivation engine 201 utilizes various software tools for performing such a simulation, including, but not limited to, Ansys® HFSS, Ansys® Maxwell, Matlab®, Siemens® PSS, etc.

In step 806, scaling engine 202 of power-noise evaluator 102 scales the modeled system impedance profile and the processor current profile for the second system (e.g., computing device 101B, processor of computing device 101B), where the scaling is made based on the design change.

As discussed above, scaling, as used herein, refers to adjusting the simulated electrical characteristics of a system (e.g., impedance profile, processor current profile) to match the behavior of a new, modified system design thereby replicating the impact of the design change in the simulation environment.

A design change of a system, as used herein, refers to modifying the physical layout, power and/or current of the physical components (e.g., processor) within a system, which modifies the amount of electrical noise generated while it operates thereby modifying the power-noise profile of the system. The power-noise profile, as used herein, refers to a representation, such as a graphical representation, of the noise level (in terms of power) across different frequencies within a power supply or circuit thereby showing how much electrical noise is present at various frequencies.

In one embodiment, such a design change of a first system (e.g., computing system 101A) may be reflected in the design of a second system (e.g., computing system 101B). Reflect, as used herein, refers to the design changes between the first and second systems that are exhibited on the second system. That is, such a design change may correspond to the difference in design between the first and second systems. That is, such a design change may correspond to the difference in design between the first and second systems.

In one embodiment, such a design change may correspond to a design technology change and/or a design power or current change. A design technology change, as used herein, refers to a change in the physical layout (e.g., place, connection) of the physical components or the characteristics and properties (e.g., type, physical properties) of the physical components of the second system. A design power or current change, as used herein, refers to the change in the power or current (e.g., voltage, current, impedance, noise of voltage, noise of current, etc.) of the physical components of the second system.

In one embodiment, scaling engine 202 scales the modeled system impedance profile and the processor current profile to reflect a design change in a second system (e.g., computing device 101B, processor of computing device 101B) by scaling the capacitances in the modeled impedance profile to reflect a design technology change in the second system.

In one embodiment, scaling engine 202 scales the capacitances in the modeled impedance profile to reflect a design technology change in the second system by calculating new capacitance values based on the altered physical layout and/or characteristics and/or properties of the physical components in the second system. For example, such new capacitance values may be computed using the capacitance formula (C=&A/d, where & is the dielectric constant, A is the surface area of the conductor plates in the capacitor, and d is the distance between the conductor plates) and adjusting the corresponding capacitance values in the impedance profile. In one embodiment, such scaling factors are derived from the changes in the dielectric constant or conductor geometry.

Scaling engine 202 utilizes various software tools for scaling the capacitances in the modeled impedance profile to reflect a design technology change in the second system, which may include, but are not limited to, Altium Designer®, Cadence® Allegro, Mentor Graphics® HyperLynx, etc.

Furthermore, in one embodiment, scaling engine 202 scales the modeled system impedance profile and the processor current profile to reflect a design change in a second system (e.g., computing device 101B, processor of computing device 101B) by scaling the processor current profile to reflect a design power or current change in the second system.

In one embodiment, scaling engine 202 scales the processor current profile to reflect a design power or current change in the second system by adjusting the current values proportionally based on the power/current ratio difference between the first and second systems. In one embodiment, such an adjustment is achieved by multiplying the current values of the processor current profile by a scaling factor derived from the power/current change ratio.

Scaling engine 202 utilizes various software tools for scaling the processor current profile to reflect a design power or current change in the second system, which may include, but are not limited to, turbostat, LTpowerPlanner®, etc.

An illustration of scaling the modeled system impedance profile and processor current profile to reflect a design change in the second system is provided in FIGS. 5 and 6.

FIG. 5 illustrates the non-scaled output 501 and the scaled output 502 for a trivial workload (e.g., dl/dt workload).

FIG. 6 illustrates the non-scaled output 601 and the scaled output 602 for a non-trivial workload.

In step 807, convolution engine 203 of power-noise evaluator 102 convolves the scaled processor current profile with the scaled modeled system impedance profile to generate a power-noise profile of the second system (e.g., computing device 101B, processor of computing device 101B).

As stated above, convolution, as used herein, refers to a mathematical operation performed on two functions that produces a third function.

In the context of convolving the scaled processor current profile with the scaled modeled system impedance profile to generate a power-noise profile of the second system, convolution involves calculating how the current fluctuations interact with the system impedance to produce voltage drops and resulting power noise at different points in time. In one embodiment, convolution engine 203 performs convolution by multiplying each point of the current profile with the corresponding point of the impedance profile after shifting one relative to the other and summing up the results across all time points.

In one embodiment, convolution engine 203 performs such a convolution by multiplying the two profiles in the frequency domain after scaling them appropriately to account for the system changes between the first and second systems. In one embodiment, the scaled processor current profile and the scaled modeled system impedance profile are converted to the frequency domain, such as via the Fast Fourier Transform (FFT) algorithm. The frequency domain representations of the scaled processor current profile and the scaled modeled system impedance profile are multiplied element-wise. Such a multiplication performs the convolution operation in the time domain. Convolution engine 203 then performs an inverse FFT on such a product to obtain the power-noise profile in the time domain, which represents the impact on the power-noise profile due to the design change for non-trivial workloads.

In one embodiment, throttling logic may be incorporated into the simulation discussed herein to represent a design methodology change. Throttling logic, as used herein, refers to a set of rules that intentionally limits the rate at which something happens, such as restricting the number of tasks or operations in a workload to be handled per unit of time.

In step 808, the design change is implemented on the first system when the power-noise profile is within an acceptable range, which may be user-designated.

In this manner, the impact of a design change of a system (e.g., computing system, processor, etc.) can be accurately and flexibly projected on the system power-noise profile for a broader class of workloads, including non-trivial workloads.

Furthermore, the principles of the present disclosure improve the technology or technical field involving power-noise simulations.

As discussed above, the purpose of a power-noise simulation is to identify potential issues related to power supply noise, such as voltage drops, spikes, or ripple, which can disrupt signal integrity and cause malfunctions in sensitive circuits. The simulation may include models of power supply components, such as capacitors, inductors, and voltage regulators, as well as the circuit's power distribution network, to accurately represent how noise propagates through the system. Furthermore, simulations can analyze various aspects of power noise, including its frequency spectrum, amplitude, and the impact on critical signal timings (jitter). By running simulations with different design parameters, engineers can identify areas for improvement to mitigate power noise, such as adding decoupling capacitors or optimizing the power delivery network layout. Power-noise simulations are typically performed on high-speed digital circuits (where sensitive signals can be easily corrupted by power supply fluctuations), power electronics (where the switching noise generated by power converters and its impact on the system are analyzed), and embedded systems (where the reliable operation of critical components in constrained power environments is ensured). Unfortunately, current power-noise simulation techniques are only capable of projecting the impact of limited design changes (e.g., capacitance change) of a system (e.g., computing system, processor, etc.) on the system power-noise profile observed on a limited class of workloads (e.g., dl/dt step function, which corresponds to the derivative of a step function with respect to time “t”). A “power-noise profile” refers to a representation, such as a graphical representation, of the noise level (in terms of power) across different frequencies within a power supply or circuit thereby showing how much electrical noise is present at various frequencies. While such existing approaches provide some insight into the power-noise impact of a system design change (e.g., capacitance change), such approaches lack accuracy and flexibility.

Embodiments of the present disclosure improve such technology by applying a workload to a first system. A modeled system impedance profile of the first system may then be derived. A modeled system impedance profile, as used herein, refers to a representation, including a graphical representation, of how the impedance of a system changes across a range of frequencies. In one embodiment, the modeled system impedance profile is calculated using a mathematical model that simulates the system's electrical behavior, such as showing how much resistance the system presents to current flow at different frequencies. Furthermore, a processor current profile of the workload for the first system is derived. A processor current profile for the workload, as used herein, refers to the specific set of performance settings currently applied to a processor and optimized to handle the demands of the current workload running on the system. That is, the processor current profile of the workload defines how the processor is dynamically adjusting its speed, power consumption, and other parameters to best suit the ongoing tasks. A design change to the first system to create a second system is assumed. The modeled system impedance profile and the processor current profile for the second system are then scaled, where the scaling is made based on the design change. Scaling, as used herein, refers to adjusting the simulated electrical characteristics of a system (e.g., impedance profile, processor current profile) to match the behavior of a new, modified system design thereby replicating the impact of the design change in the simulation environment. The scaled processor current profile is convolved with the scaled modeled system impedance profile to generate a power-noise profile of the second system. Convolution, as used herein, refers to a mathematical operation performed on two functions that produces a third function. In the context of convolving the scaled processor current profile with the scaled modeled system impedance profile to generate a power-noise profile of the second system, convolution involves calculating how the current fluctuations interact with the system impedance to produce voltage drops and resulting power noise at different points in time. The design change is implemented on the first system when the power-noise profile is within an acceptable range. In this manner, the impact of a design change of a system (e.g., computing system, processor, etc.) can be accurately and flexibly projected on the system power-noise profile for a broader class of workloads, including non-trivial workloads. Furthermore, in this manner, there is an improvement in the technical field involving power-noise simulations.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A computer-implemented method for projecting a design change impact on a power-noise profile, the method comprising:
applying a workload to a first system;
deriving a modeled system impedance profile of said first system;
deriving a processor current profile of said workload for said first system;
assuming a design change to said first system to create a second system;
scaling said modeled system impedance profile and said processor current profile for said second system, wherein said scaling is made based on said design change;
convolving said scaled processor current profile with said scaled modeled system impedance profile to generate a power-noise profile of said second system; and
implementing said design change to said first system when said power-noise profile is within an acceptable range.

2. The method as recited in claim 1 further comprising:
scaling capacitances in said modeled system impedance profile to reflect a design technology change in said second system.

3. The method as recited in claim 2, wherein said design technology change comprises one or more changes to one or more physical components of said second system, wherein the one or more changes are selected from a group consisting of: place, connection, type, and physical properties.

4. The method as recited in claim 1 further comprising:
scaling said processor current profile to reflect a design power or current change in said second system.

5. The method as recited in claim 4, wherein design power or current change comprises one or more changes to one or more physical components of said second system, wherein the one or more changes are selected from the group consisting of: voltage, current, impedance, noise of voltage, and noise of current.

6. The method as recited in claim 1, wherein said processor current profile of said workload for said first system is derived by:
determining said modeled system impedance profile of said first system and an associated response function; and
deconvolving said modeled system impedance profile of said first system with a voltage trace of said workload to generate a corresponding current trace.

7. The method as recited in claim 1, wherein said first and second systems correspond to first and second processors, respectively.

8. A computer program product for projecting a design change impact on a power-noise profile, the computer program product comprising one or more computer readable storage mediums having program code embodied therewith, the program code comprising programming instructions for:
applying a workload to a first system;
deriving a modeled system impedance profile of said first system;
deriving a processor current profile of said workload for said first system;
assuming a design change to said first system to create a second system;
scaling said modeled system impedance profile and said processor current profile for said second system, wherein said scaling is made based on said design change;
convolving said scaled processor current profile with said scaled modeled system impedance profile to generate a power-noise profile of said second system; and
implementing said design change to said first system when said power-noise profile is within an acceptable range.

9. The computer program product as recited in claim 8, wherein the program code further comprises the programming instructions for:
scaling capacitances in said modeled system impedance profile to reflect a design technology change in said second system.

10. The computer program product as recited in claim 9, wherein said design technology change comprises one or more changes to one or more physical components of said second system, wherein the one or more changes are selected from a group consisting of: place, connection, type, and physical properties.

11. The computer program product as recited in claim 8, wherein the program code further comprises the programming instructions for:
scaling said processor current profile to reflect a design power or current change in said second system.

12. The computer program product as recited in claim 11, wherein design power or current change comprises one or more changes to one or more physical components of said second system, wherein the one or more changes are selected from the group consisting of: voltage, current, impedance, noise of voltage, and noise of current.

13. The computer program product as recited in claim 8, wherein said processor current profile of said workload for said first system is derived by:
determining said modeled system impedance profile of said first system and an associated response function; and
deconvolving said modeled system impedance profile of said first system with a voltage trace of said workload to generate a corresponding current trace.

14. The computer program product as recited in claim 8, wherein said first and second systems correspond to first and second processors, respectively.

15. A system, comprising:
a memory for storing a computer program for projecting a design change impact on a power-noise profile; and
a processor connected to said memory, wherein said processor is configured to execute program instructions of the computer program comprising:
applying a workload to a first system;
deriving a modeled system impedance profile of said first system;
deriving a processor current profile of said workload for said first system;
assuming a design change to said first system to create a second system;
scaling said modeled system impedance profile and said processor current profile for said second system, wherein said scaling is made based on said design change;
convolving said scaled processor current profile with said scaled modeled system impedance profile to generate a power-noise profile of said second system; and
implementing said design change to said first system when said power-noise profile is within an acceptable range.

16. The system as recited in claim 15, wherein the program instructions of the computer program further comprise:
scaling capacitances in said modeled system impedance profile to reflect a design technology change in said second system.

17. The system as recited in claim 16, wherein said design technology change comprises one or more changes to one or more physical components of said second system, wherein the one or more changes are selected from a group consisting of: place, connection, type, and physical properties.

18. The system as recited in claim 15, wherein the program instructions of the computer program further comprise:
scaling said processor current profile to reflect a design power or current change in said second system.

19. The system as recited in claim 18, wherein design power or current change comprises one or more changes to one or more physical components of said second system, wherein the one or more changes are selected from the group consisting of: voltage, current, impedance, noise of voltage, and noise of current.

20. The system as recited in claim 15, wherein said processor current profile of said workload for said first system is derived by:
determining said modeled system impedance profile of said first system and an associated response function; and
deconvolving said modeled system impedance profile of said first system with a voltage trace of said workload to generate a corresponding current trace.
